(19) United States
(12) Patent Application Publication
(10) Pub. No.: US 2025/0231895 A1
(43) Pub. Date: Jul. 17, 2025

(54) VERTICALLY STACKED HIGH BANDWIDTH STORAGE DEVICES AND ASSOCIATED SYSTEMS AND METHODS

(71) Applicant: Micron Technology, Inc., Boise, ID (US)

(72) Inventors: Lingming Yang, Meridian, ID (US); Nevil N. Gajera, Meridian, ID (US)

(21) Appl. No.: 19/007,423

(22) Filed: Dec. 31, 2024

Related U.S. Application Data
(60) Provisional application No. 63/621,227, filed on Jan. 16, 2024.

(51) Int. Cl. G06F 13/20

(52) U.S. Cl. CPC G06F 13/20; G06F 2213/40

(57) ABSTRACT

System-in-package (SiP) devices, and associated systems and methods, are disclosed herein. In some embodiments, the SiP devices include a base substrate, as well as a processing unit a high bandwidth memory (HBM) device, and a high bandwidth storage (HBS) device each carried by the base substrate. The HBM device is electrically coupled to the processing unit through a SiP bus and includes a first interface die, one or more volatile memory dies, and an HBM bus electrically coupled to the first interface die and each of the one or more volatile memory dies. The HBS device is electrically coupled to the HBM device through the SiP bus and includes a second interface die one or more non-volatile memory dies, and an HBS bus electrically coupled to the second interface die and each of the one or more non-volatile memory dies.

### CROSS-REFERENCE TO RELATED APPLICATION(S)

The present application claims priority to U.S. Provisional Patent Application No. 63/621,227, filed Jan. 16, 2024, the disclosure of which is incorporated herein by reference in its entirety.

### TECHNICAL FIELD

The present technology is generally related to vertically stacked semiconductor devices and more specifically to vertically stacked high bandwidth storage devices for semiconductor packages.

### BACKGROUND

Microelectronic devices, such as memory devices, microprocessors, and other electronics, typically include one or more semiconductor dies mounted to a substrate and encased in a protective covering. The semiconductor dies include functional features, such as memory cells, processor circuits, imager devices, interconnecting circuitry, etc. To meet continual demands on decreasing size, wafers, individual semiconductor dies, and/or active components are typically manufactured in bulk, singulated, and then stacked on a support substrate (e.g., a printed circuit board (PCB) or other suitable substrates). The stacked dies can then be coupled to the support substrate (sometimes also referred to as a package substrate) through bond wires in shingle-stacked dies (e.g., dies stacked with an offset for each die) and/or through substrate vias (TSVs) between the dies and the support substrate.

### BRIEF DESCRIPTION OF THE DRAWINGS

FIG. 1 is a schematic diagram illustrating an environment that incorporates a high bandwidth memory architecture.

FIG. 2 is a schematic diagram illustrating an environment that incorporates a high bandwidth memory architecture in accordance with some embodiments of the present technology.

FIG. 3 is a partially schematic cross-sectional diagram of a system-in-package configured in accordance with some embodiments of the present technology.

FIG. 4 is a partially schematic exploded view of a high bandwidth storage device configured in accordance with some embodiments of the present technology.

FIG. 5 is a flow diagram of a process for operating a system-in-package device in accordance with some embodiments of the present technology.

FIG. 6 is a flow diagram of a process for operating a high bandwidth storage device in accordance with some embodiments of the present technology.

FIG. 7 is a partially schematic cross-sectional diagram of a high bandwidth storage device configured in accordance with further embodiments of the present technology.

FIGS. 8A and 8B are flow diagrams of processes for powering a system-in-package device down and powering a system-in-package device up, respectively, using a high bandwidth storage device in accordance with some embodiments of the present technology.

The drawings have not necessarily been drawn to scale. Further, it will be understood that several of the drawings have been drawn schematically and/or partially schematically. Similarly, some components and/or operations can be separated into different blocks or combined into a single block for the purpose of discussing some of the implementations of the present technology. Moreover, while the technology is amenable to various modifications and alternative forms, specific implementations have been shown by way of example in the drawings and are described in detail below. The intention, however, is not to limit the technology to the particular implementations described.

### DETAILED DESCRIPTION

High data reliability, high speed of memory access, lower power consumption, and reduced chip size are features that are demanded from semiconductor memory. In recent years, three-dimensional (3D) memory devices have been introduced. Some 3D memory devices are formed by stacking memory dies vertically, and interconnecting the dies using through-silicon (or through-substrate) vias (TSVs). Benefits of the 3D memory devices include shorter interconnects (which reduce circuit delays and power consumption), a large number of vertical vias between layers (which allow wide bandwidth buses between functional blocks, such as memory dies, in different layers), and a considerably smaller footprint. Thus, the 3D memory devices contribute to higher memory access speed, lower power consumption, and chip size reduction. Example 3D memory devices include Hybrid Memory Cube (HMC) and High Bandwidth Memory (HBM). For example, HBM is a type of memory that includes a vertical stack of dynamic random-access memory (DRAM) dies and an interface die (which, e.g., provides the interface between the DRAM dies of the HBM device and a host device).

In a system-in-package (SiP) configuration, HBM devices may be integrated with a host device (e.g., a graphics processing unit (GPU) and/or computer processing unit (CPU)) using a base substrate (e.g., a silicon interposer, a substrate of organic material, a substrate of inorganic material and/or any other suitable material that provides interconnection between GPU/CPU and the HBM device and/or provides mechanical support for the components of a SiP device), through which the HBM devices and host communicate. Because traffic between the HBM devices and host device resides within the SiP (e.g., using signals routed through the silicon interposer), a higher bandwidth may be achieved between the HBM devices and host device than in conventional systems. In other words, the TSVs interconnecting DRAM dies within an HBM device, and the silicon interposer integrating HBM devices and a host device, enable the routing of a greater number of signals (e.g., wider data buses) than is typically found between packaged memory devices and a host device (e.g., through a printed circuit board (PCB)). The high bandwidth interface within a SiP enables large amounts of data to move quickly between the host device (e.g., GPU/CPU) and HBM devices during operation. For example, the high bandwidth channels can be on the order of 1000 gigabytes per second (GB/s, sometimes also referred to as gigabits (Gb)). It will be appreciated that such high bandwidth data transfer between a GPU/CPU and the memory of HBM devices can be advantageous in various high-performance computing applications, such as video rendering, high-resolution graphics applications, artificial intelligence and/or machine learning (AI/ML) computing systems and other complex computational systems, and/or various other computing applications.

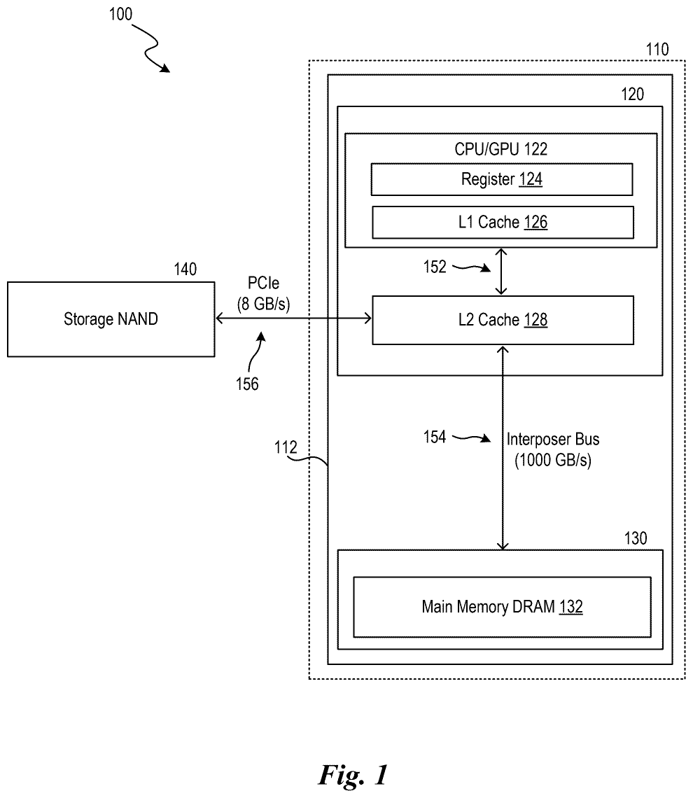

FIG. 1 is a schematic diagram illustrating an environment 100 that incorporates a high bandwidth memory architecture. As illustrated in FIG. 1, the environment 100 includes a SiP device 110 having one or more processing devices 120 (one illustrated in FIG. 1, sometimes also referred to herein as one or more “hosts”), and one or more HBM devices 130 (one illustrated in FIG. 1), integrated with a silicon interposer 112 (or any other suitable base substrate). The environment 100 additionally includes a storage device 140 coupled to the SiP device 110. The processing devices(s) 120 can include one or more CPUs and/or one or more GPUs, referred to as a CPU/GPU 122, each of which may include a register 124 and a first level of cache 126. The first level of cache 126 (also referred to herein as “L1 cache”) is communicatively coupled to a second level of cache 128 (also referred to herein as “L2 cache”) via a first communication path 152. In the illustrated embodiment, the L2 cache 128 is incorporated into the processing device(s) 120. However, it will be understood that the L2 cache 128 can be integrated into the SiP device 110 separate from the processing device(s) 120. Purely by way of example, the processing device(s) 120 can be carried by a base substrate (e.g., an interposer that is itself carried by a package substrate) adjacent to the L2 cache 128 and in communication with the L2 cache 128 via one or more signal lines (or other suitable signal route lines) therein. The L2 cache 128 may be shared by one or more of the processing devices 120 (and CPU/GPU 122 therein). During operation of the SiP device 110, the CPU/GPU 122 can use the register 124 and the L1 cache 126 to complete processing operations, and attempt to retrieve data from the larger L2 cache 128 whenever a cache miss occurs in the L1 cache 126. As a result, the multiple levels of cache can help accelerate the average time it takes for the processing device(s) 120 to access data, thereby accelerating the overall processing rates.

As further illustrated in FIG. 1, the L2 cache 128 is communicatively coupled to the HBM device(s) 130 through a second communication channel 154. As illustrated, the processing device(s) 120 (and the L2 cache 128 therein) and HBM device(s) 130 are carried by and electrically coupled (e.g., integrated by) the silicon interposer 112. The second communication channel 154 is provided by the silicon interposer 112 (e.g., the silicon interposer includes and routes the interface signals forming the second communication channel, such as through one or more redistribution layers (RDLs)). As additionally illustrated in FIG. 1, the L2 cache 128 is also communicatively coupled to a storage device 140 through a third communication channel 156. As illustrated, the storage device 140 is outside of the SiP device 110, and utilizes signal routing components that are not contained within the silicon interposer 112 (e.g., between a packaged SiP device 110 and packaged storage device 140). For example, the third communication channel 156 may be a peripheral bus used to connect components on a motherboard or PCB, such as a Peripheral Component Interconnect Express (PCIe) bus. As a result, during operation of the SiP device 110, the processing device(s) 120 can read data from and/or write data to the HBM device(s) 130 and/or the storage device 140, through the L2 cache 128.

In the illustrated environment 100, the HBM devices 130 include one or more stacked volatile memory dies 132 (e.g., DRAM dies, one illustrated schematically in FIG. 1) coupled to the second communication channel 154. As explained above, the HBM device(s) 130 can be located on the silicon interposer 112, on which the processing device(s) 120 are also located. As a result, the second communication channel 154 can provide a high bandwidth (e.g., on the order of 1000 GB/s) channel through the silicon interposer 112. Further, as explained above, each HBM device(s) 130 can provide a high bandwidth channel (not shown) between the volatile memory dies 132 therein. As a result, data can be communicated between the processing device(s) 120 and the HBM device(s) 130 (and the volatile memory dies 132 therein) at high speeds, which can be advantageous for data-intensive processing operations. Although the HBM device(s) 130 of the SiP device 110 provide relatively high bandwidth communication, their integration on the silicon interposer 112 suffers from certain shortcomings. For example, each HBM device(s) 130 may provide a limited amount of storage (e.g., on the order of 16 GB each), where the total storage provided by all of the HBM devices 130 may be insufficient to maintain the working data set of an operation to be performed by the SiP device 110. Additionally, or alternatively, the HBM device(s) 130 are made up of volatile memory (e.g., each requires power to maintain the stored data, and the data is lost once the HBM device is powered down and/or suffers an unexpected power loss).

In contrast to the characteristics of the HBM devices 130, the storage device 140 can provide a large amount of storage (e.g., on the order of terabytes and/or tens of terabytes). The greater capacity of the storage device 140 is typically sufficient to maintain the working data set of the complex operations to be performed by the SiP device 110. Additionally, the storage device 140 is typically non-volatile (e.g., made up of NAND-based storage, such as NAND flash, as illustrated in FIG. 1), and therefore retains stored data even after power is lost. However, as discussed above, the storage device 140 is located external to the SiP device 110 (e.g., not placed on the silicon interposer 112), and instead coupled to the SiP device 110 through a communication channel (e.g., PCIe) routed over a motherboard, system board, or other form of PCB. As a result, the third communication channel 156 can have a relatively low bandwidth (e.g., on the order of 8 GB/s), significantly lower than the bandwidth of the second communication channel 154. Consequently, processing operations involving large amounts of data (e.g., graphics rendering, AI/ML processes, and the like), which do not fit within the storage capacities of the HBM device 130, are bottlenecked by the low bandwidth of the third communication channel 156 as data moves between the storage device 140 and the SiP device 110. Additionally, power-down/power-up operations that require data to move between the storage device 140 and the SiP device 110 are bottlenecked by the relatively low bandwidth of the third communication channel 156.

High bandwidth storage (HBS) devices, and associated systems and methods, that address the shortcomings discussed above are disclosed herein. The HBS device can include an interface die and one or more non-volatile memory dies (e.g., NAND dies, NOR dies, PCM dies, FeRAM dies, MRAM dies, and/or any other suitable dies). The HBS device can also include one or more TSVs that electrically couple the interface die and the one or more non-volatile memory dies to establish communication paths therebetween. As described herein, the TSVs can provide a wide communication path (e.g., on the order of 1024 I/Os) between the interface die and the non-volatile memory dies, enabling high bandwidth therebetween. Further, the HBS device can be integrated into a SiP device that includes one or more of the HBS devices, one or more HBM devices, and one or more host devices (e.g., processing devices comprising CPUs and/or GPUs). In such embodiments, the HBS devices, HBM devices, and host devices of the SiP device are placed on and/or integrated with a silicon interposer that includes high bandwidth communication channels between the HBS devices, HBM devices, and/or host devices. As a result, the HBS devices disclosed herein can significantly expand the storage available within the SiP devices, thereby reducing the frequency with which large sets of data must be communicated through the bottleneck described above.

Advantageously, large sets of data can be loaded into the HBS device (e.g., from an external storage component) through a low bandwidth communication path (e.g., PCIe) during an initialization phase. Then, during processing, portions of the large data set may be transferred between the HBS devices and the HBM devices, via a high bandwidth communication path (e.g., a SiP bus) coupled therebetween, based on the portions of the large data set being processed at a time (e.g., the working data set). In this example, the HBM devices can provide functionality similar to the HBM device 130 discussed above with reference to FIG. 1. That is, for example, the HBM devices can provide DRAM-based storage of a working data set, accessible via a high bandwidth interface to the host devices. Once a first portion of the data set has been processed, a result can be saved to the HBS devices and a second portion of the data set can be loaded into the HBM devices, through the high bandwidth communication path, from the data set in the HBS devices. The process can then be repeated for the first, second, etc., portions of the data set to use the data set in any number of computations at the host device without needing to load the data set through the low bandwidth communication path. In a specific, non-limiting example, the data set can include training data for an artificial intelligence and/or machine learning (AI/ML) model that needs to be accessed and/or processed hundreds, thousands, tens of thousands, or more of times to train the AI/ML model. In this example, the HBS devices can significantly reduce the processing time by requiring the data set to only be communicated through the low bandwidth channel once during an initialization phase, and subsequently provide high bandwidth transfer of the data set (or portions thereof) between the HBS devices, HBM devices, and/or host devices during a processing phase (e.g., reducing the processing time by hundreds of seconds, thousands of seconds, tens of thousands of seconds, or more).

Additionally, or alternatively, the HBS devices can provide non-volatile storage for the data stored in the HBM device (e.g., the HBS devices operate as a non-volatile HBM device on the SiP). In said embodiments, the HBS devices can save data from and/or restore data to the HBM devices and/or the host devices in response to various events, such as power-down and/or power-up, losses of power, errors in processing, and/or the like. For example, in response to a power-down or idle request, data from the HBM devices and/or any of the caches can be stored in the HBS devices to store a present (or “current”) state of the SiP device. Because the HBS devices are available through the high bandwidth communication path, the request can be satisfied much faster than communicating the data to an external storage component (e.g., on the order of tens of milliseconds instead of several seconds). Similarly, in response to a power-up or wake-up request being received, the data can be moved back to the HBM devices and/or cache(s) through the high bandwidth communication paths. As a result, the saved state of the SiP can be restored, and the power-up request can be answered, within tens of milliseconds instead of the several seconds required when data must be loaded from the separate storage component.

Additional details on the HBS devices, SiP devices having HBS devices, and associated systems and methods, are set out below. For ease of reference, semiconductor packages (and their components) are sometimes described herein with reference to front and back, top and bottom, upper and lower, upwards and downwards, and/or horizontal plane, x-y plane, vertical, or z-direction relative to the spatial orientation of the embodiments shown in the figures. It is to be understood, however, that the semiconductor assemblies (and their components) can be moved to, and used in, different spatial orientations without changing the structure and/or function of the disclosed embodiments of the present technology. Additionally, signals within the semiconductor packages (and their components) are sometimes described herein with reference to downstream and upstream, forward and backward, and/or read and write relative to the embodiments shown in the figures. It is to be understood, however, that the flow of signals can be described in various other terminology without changing the structure and/or function of the disclosed embodiments of the present technology.

Further, although the memory device architectures disclosed herein are primarily discussed in the context of expanding memory capacity to improve artificial intelligence and machine learning models and/or to create non-volatile memory in a dynamic random-access memory (DRAM) component, one of skill in the art will understand that the scope of the technology is not so limited. For example, the systems and methods disclosed herein can also be deployed to expand the available high bandwidth memory for various other applications that process significant volumes of data (e.g., video rendering, decryption systems, and the like).

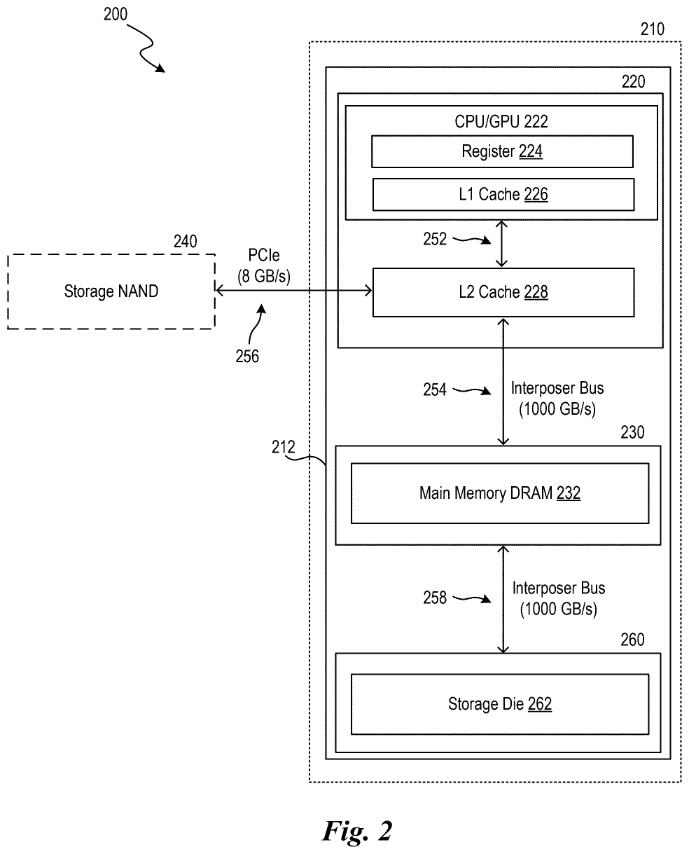

FIG. 2 is a schematic diagram illustrating an environment 200 that incorporates an HBM architecture as well as an HBS architecture in accordance with some embodiments of the present technology. Similar to the environment 100 discussed above, the environment 200 includes a SiP device 210 having one or more processing devices 220 (one illustrated in FIG. 2), one or more HBM devices 230 (one illustrated in FIG. 2), and one or more storage devices 240 (one illustrated in FIG. 2). Further, the processing device(s) 220 and the HBM device(s) 230 are each integrated on an interposer 212 (e.g., a silicon interposer, another organic interposer, an inorganic interposer, and/or any other suitable base substrate) that can include one or more signal routing lines. The processing device(s) 220 is driven by a CPU/GPU 222 that includes a register 224 and an L1 cache 226. The L1 cache 226 is communicatively coupled to an L2 cache 228 via a first communication channel 252. The L2 cache 228 is communicatively coupled to a stack of one or more volatile memory dies 232 (e.g., DRAM dies) in the HBM devices 230 through a second communication channel 254 and coupled to the storage device 240 through a third communication channel 256. Still further, the second communication channel 254 can have a relatively high bandwidth (e.g., on the order of 1000 GB/s) while the third communication channel 256 can have a relatively low bandwidth (e.g., on the order of 8 GB/s).

In the embodiment illustrated in FIG. 2, the SiP device 210 also includes one or more HBS devices 260 (one illustrated in FIG. 2) that each include a stack of one or more storage dies 262 (e.g., NAND dies, NOR dies, or other suitable non-volatile memory dies). The storage dies 262 can provide a relatively large storage capacity (e.g., on the order of hundreds of gigabytes and/or a terabyte), as well as non-volatile storage within the SiP device 210. Further, as discussed in more detail below, the HBS device 260 (and the storage dies 262 therein) can be coupled to the HBM devices 230 and/or the processing devices 220 via a fourth communication channel 258. The fourth communication channel 258 can have a relatively high bandwidth (e.g., on the order of 1000 GB/s) that is generally similar to (or equivalent to) the second communication channel 254. As a result, the HBS device 260 provides the SiP device 210 with high bandwidth access to a large amount of non-volatile storage, rather than needing to access the storage devices 240 through the third communication channel 256. Although FIG. 2 illustrates an embodiment in which the HBS devices 260 are coupled to the HBM devices 230 via the fourth communication channel 258, in embodiments the fourth communication channel 258 can additionally or alternatively couple the HBS devices 260 to the processing devices 220, and/or an additional communication channel (not shown) can couple the HBS devices 260 to the processing devices 220.

The combination of volatile memory (e.g., via the HBM devices 230) and non-volatile memory (e.g., via the HBS devices 260) within the SiP device 210 can provide various advantages. For example, volatile memory such as DRAM typically provides accesses (e.g., reads and writes) that are relatively faster than non-volatile memory such as NAND, but at a lower density (e.g., storage capacity within a die footprint). In contrast, non-volatile memory such as NAND typically provides a high storage density, but can be relatively slow to access and can incur certain overheads (e.g., wear-leveling). As a result, the volatile memory die(s) 232 can provide low-latency fast communication, making data quickly available to the processing device(s) 220 of the SiP device 210 as needed. The non-volatile memory dies 262 can provide a relatively large memory capacity that is “closer” to the processing devices 220 (e.g., accessible within the SiP device 210 through high bandwidth buses, such as the fourth communication channel 258, the second communication channel 254, and/or other communication channels not shown) as compared to the storage device 240 (e.g., accessible through a slower channel, such as PCIe). Additionally, the non-volatile memory dies 262 can provide non-volatile memory capacity that is closer to the processing devices 220 and/or the volatile memory dies 232 as compared to the storage device 240 and/or other non-volatile memory capacity.

As a result, for example, a relatively large data set can be communicated from the storage device 240 to the non-volatile memory die(s) 262 in the HBS device(s) 260 to initiate a processing operation (e.g., to run an AI/ML algorithm). For example, an entire data set needed for an AI/ML operation can be copied from the storage device 240 to the HBS device(s) 260. Subsets of the data set can then be rapidly communicated from the HBS device(s) 260 to the HBM device(s) 230 via the high bandwidth of the fourth communication channel 258, then to the processing device(s) 220 via the high bandwidth of the second communication channel 254 (sometimes also referred to herein as a “high bandwidth communication path”). When the processing devices(s) 220 is finished processing the subset, a new subset can be quickly written into the HBM device(s) 230 from the HBS device(s) 260, without needing to retrieve the data from the storage device 240 with the attendant bottleneck in the third communication channel 256 (sometimes also referred to herein as a “low bandwidth communication path”). Further, the processing operation can be iteratively executed (e.g., the hundreds, thousands, tens of thousands, or more iterations often used for an AI/ML algorithm) without requiring the large data set to be communicated through the bottleneck multiple times. Thus, the inclusion of the HBS device(s) 260 can increase the processing speed of the SiP device 210, thereby increasing the functionality of the environment 200. Further, because communicating data through high bandwidth channels is more efficient than communicating data through low bandwidth channels, the inclusion of the HBS device(s) 260 can reduce the overall power consumption of the environment 200 and/or reduce the heat generated by the environment 200.

Additionally, or alternatively, the non-volatile memory die(s) 262 in the HBS device(s) 260 can save a copy of the data being processed and/or an overall state of the SiP device 210 in a non-volatile component. As a result, for example, the state of the HBM device(s) 230 does not need to be written between the volatile memory die(s) 232 and the storage device 240 to power down and/or power up. Instead, the state can be written to the non-volatile memory die(s) 262 in the HBS device(s) 260. Thus, a power-down operation (sometimes also referred to herein as a “sleep operation” and/or an “idle operation”) can be completed almost instantly (e.g., by saving a copy through the high bandwidth of the fourth communication channel 258). Similarly, a power-up operation (sometimes also referred to herein as a “wake up operation”) can write the state back to the volatile memory die(s) 232 in the HBM device(s) 230 from the non-volatile memory die(s) 262 in the HBS device(s) 260 via the fourth communication channel 258, instead of from the storage device 240 via the third communication channel 256. As a result, the power-down and/or power-up operations can be accelerated from several seconds to much less than one second (e.g., tens of milliseconds). Additionally, or alternatively, the HBS device(s) can protect against a loss of power and/or other processing errors in the environment 200. For example, because the HBM device(s) 230 can save a current state of SiP device 210 (e.g., a current state of the HBM device(s) 230 and/or the processing devices 220) to the HBS device(s) 260 in milliseconds, the HBM device(s) 230 can save a current state of the SiP device 210 to the HBS device(s) 260 after a predetermined period (e.g., every ten seconds, minute, five minutes, thirty minutes, hour, two hours, twelve hours, day, and/or any other suitable period) and/or after various processing milestones without significantly delaying processing at the SiP device 210. As a result, a loss of power and/or other error can return to the last saved state before the loss of power and/or error, thereby losing less processing time and/or less data (e.g., restoring half of a processing operation rather than needing to start over).

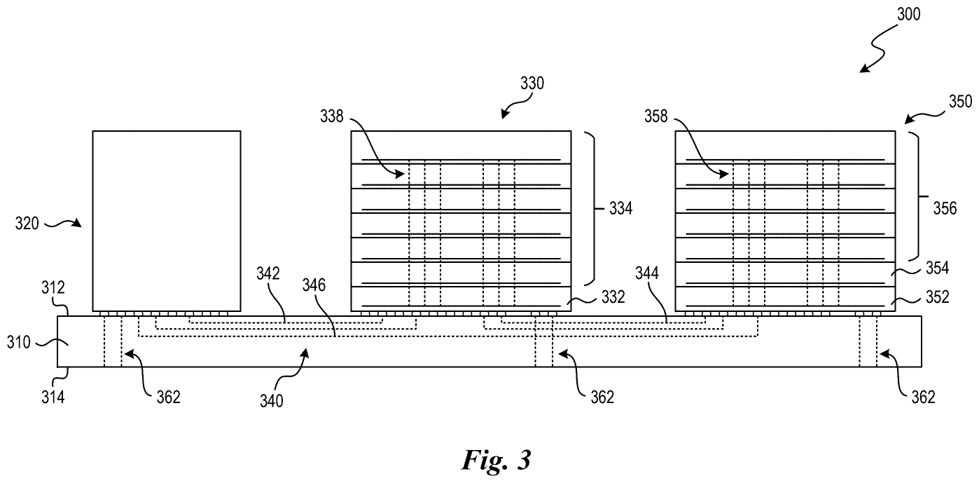

The environment 200 can be configured to perform any of a wide variety of suitable computing, processing, storage, sensing, imaging, and/or other functions. For example, representative examples of systems that include the environment 200 (and/or components thereof, such as the SiP device 210) include, without limitation, computers and/or other data processors, such as desktop computers, laptop computers, Internet appliances, hand-held devices (e.g., palm-top computers, wearable computers, cellular or mobile phones, automotive electronics, personal digital assistants, music players, etc.), tablets, multi-processor systems, processor-based or programmable consumer electronics, network computers, and minicomputers. Additional representative examples of systems that include the environment 200 (and/or components thereof) include lights, cameras, vehicles, etc. With regard to these and other examples, the environment 200 can be housed in a single unit or distributed over multiple interconnected units, e.g., through a communication network, in various locations on a motherboard, and the like. Further, the components of the environment 200 (and/or any components thereof) can be coupled to various other local and/or remote memory storage devices, processing devices, computer-readable storage media, and the like. Additional details on the architecture of the environment 200, the SiP device 210, the HBM device(s) 230, and processes for operation thereof, are set out below with reference to FIGS. 3-8B.

FIG. 3 is a partially schematic cross-sectional diagram of a SiP device 300 configured in accordance with some embodiments of the present technology. As illustrated in FIG. 3, the SiP device 300 includes a base substrate 310 (e.g., a silicon interposer, another suitable organic substrate, an inorganic substrate, and/or any other suitable material), as well as a processing unit 320, an HBM device 330, and an HBS device 350 each integrated with an upper surface 312 of the base substrate 310. For example, as discussed in more detail below, each of the processing unit 320, the HBM device 330, and the HBS device 350 are communicatively coupled by a SiP bus 340 formed in the base substrate 310.

In the illustrated embodiments, the processing unit 320, is illustrated as a single component. However, as discussed above, the processing unit 320 can include a CPU/GPU component, a register, an L1 cache, an L2 cache, and/or various other suitable components integrated into a single package.

The HBM device 330 includes a stack of semiconductor dies. The stack of semiconductor dies in the HBM device 330 includes an interface die 332, one or more volatile memory dies 334 (six illustrated in FIG. 3) carried by the interface die 332, and one or more through substrate vias 338 (“TSVs 338,” six illustrated schematically in FIG. 3). The TSVs 338 (sometimes also referred to herein as part of (or forming) an “HBM bus”) extend from the interface die 332 through each of the volatile memory dies 334. The TSVs 338 allow each of the dies to communicate data within the HBM device 330 (e.g., between the volatile memory dies 334 (e.g., DRAM dies) and the interface die 332) at a relatively high rate (e.g., on the order of 100 GB/s, 1000 GB/s, or greater).

Further, the processing unit 320 is coupled to the HBM device 330 through a first portion 342 of the SiP bus 340 that includes one or more route lines (two illustrated schematically in FIG. 3) formed into (or on) the base substrate 310. In various embodiments, the route lines of the first portion 342 can include one or more metallization layers formed in one or more RDL layers of the base substrate 310 and/or one or more vias interconnecting the metallization layers and/or traces. Further, it will be understood that the processing unit 320 and the HBM device 330 can each be coupled to the route lines of the first portion 342 via interconnects (e.g., solder balls, micro bumps, posts (e.g., copper posts), and/or any other suitable component), metal-metal bonds, and/or any other suitable conductive bonds. In turn, the signal route lines of the first portion 342 and the TSVs 338 of the HBM device 330 allow the dies in the HBM device 330 and the processing unit 320 to communicate data at the relatively high rate (e.g., on the order of 100 GB/s, 1000 GB/s, or greater).

As further illustrated in FIG. 3, the HBS device 350 also includes a stack of semiconductor dies. In the illustrated embodiments, the stack of semiconductor dies in the HBS device 350 includes an interface die 352, one or more volatile memory dies 354 (one illustrated in FIG. 3) carried by the interface die 352, one or more non-volatile memory dies 356 (five illustrated in FIG. 3) carried by the interface de 352, and one or more TSVs 358 (six illustrated schematically in FIG. 3). It will be understood that, in some embodiments, the HBS device 350 does not include the volatile memory die(s) 354 (e.g., includes only the interface die 352 and the non-volatile memory dies 356). The omission of the volatile memory die(s) 354 can help simplify a construction of the die stack by limiting the number of different types of semiconductor dies stacked together.

The TSVs 358 (sometimes also referred to herein as part of (or forming) an “HBM bus”) extend from the interface die 332 through each of the volatile and non-volatile memory dies 354, 356. Similar to the TSVs 338 discussed above, the TSVs 358 allow each of the dies to communicate data within the HBS device 350 (e.g., between the volatile memory die(s) 354 (e.g., DRAM dies) and the non-volatile memory dies 356 (e.g., NAND dies, NOR dies, and/or any other suitable dies), between the volatile memory die(s) 354 and the interface die 352, and/or between the non-volatile memory dies 358 and the interface die 352) at the relatively high rate (e.g., on the order of 100 GB/s, 1000 GB/s, or greater).

Further, the HBM device 330 is coupled to the HBS device 350 through a second portion 344 of the SiP bus 340 that includes one or more route lines (two illustrated schematically in FIG. 3) formed into (or on) the base substrate 310. As discussed above, the route lines can include one or more metallization layers formed in one or more RDL layers of the base substrate 310 and/or one or more vias interconnecting the metallization layers and/or traces. Further, it will be understood that the HBM device 330 and the HBS device 350 can each be coupled to the route lines of the second portion 344 via interconnects (e.g., solder balls, micro bumps, posts (e.g., copper posts), and/or any other suitable component), metal-metal bonds, and/or any other suitable conductive bonds. In turn, the signal route lines of the second portion 344 and the TSVs 338 of the HBM device 330, and the TSVs 358 of the HBS device 350 allow the dies in the HBM device 330 and the dies in the HBS device 350 to communicate data at the relatively high rate (e.g., on the order of 100 GB/s, 1000 GB/s, or greater).

In some embodiments, the interface die 352 includes a controller for the volatile memory dies 354 and/or the non-volatile memory dies 356, allowing the interface die 352 to control the HBS device 350 in response to various read and write requests. By positioning the controller within the interface die 352, the HBS device 350 can reduce the number of signals that must be communicated over the SiP bus 340. In various other embodiments, however, the controller for the volatile memory dies 354 and/or the non-volatile memory dies 356 is positioned in the processing unit 320 and/or the HBM device 330. The non-volatile memory dies 356 provide a relatively large, non-volatile storage (e.g., on the order of hundreds of gigabytes, a terabyte, and/or the like) within the SiP device 300. As a result, relatively large data sets and/or the like can be stored fully within the SiP device 300, reducing the need to retrieve data from an external storage.

For example, as discussed in more detail below, during operation of the SiP device 300, the processing unit 320 can send a request for a subset of a large data set to the HBM device 330 through the first portion 342 of the SiP bus 340. The HBM device 330 can check whether the subset is stored in the volatile memory dies 334 and, if not, forward the request and/or generate a new request for the data to the HBS device 350 through the second portion 344 of the SiP bus 340. The HBS device 350 can then write a copy of the subset of the data to the HBM device 330 through the second portion 344 of the SiP bus 340, thereby allowing the HBM device 330 to send the subset of the data to the processing unit 320 for processing through the first portion 342 of the SiP bus 340. Once the subset has been processed (and/or at various times during the processing), the processing unit 320 can write a result of the processing into the HBM device 330 through the first portion 342 of the SiP bus 340. In turn, the HBM device 330 can write the result of the processing to the HBS device 350 through the second portion 344 of the SiP bus 340. The processing unit 320 can then send a request for another subset of the data set to the HBM device 330, and so on. In some embodiments, the process can be repeated, as necessary, any number of times (e.g., when iteratively training a machine learning model on a data set). As a result, when a data set is available in the HBS device 350, the SiP device 300 is able to complete any number of iterations of a processing operation without communicating with an external storage component (e.g., via a PCI bus), thereby avoiding (or reducing the passages through) the bottleneck discussed in more detail above and increasing an overall processing speed of the SiP device 300.

In some embodiments, the volatile memory die(s) 354 act as a buffer for the HBS device 350 to increase a response speed of the HBS device 350. For example, as discussed in more detail below, the HBS device 350 can receive a first request instructing the interface die 352 to load a subset of data into the volatile memory die(s) 354 from the non-volatile memory dies 356 for an upcoming request (e.g., when the processing unit 320 knows which data it will need next), then receive a second request instructing the interface die 352 to send the data to the HBM device 330 and/or the processing unit 320 from the volatile memory die(s) 354. By loading the subset of the data into the volatile memory die(s) 354 in response to the first request, the HBS device 350 can help reduce a response time to the second request, thereby further increasing the overall processing speed of the SiP device 300.

In some embodiments, the processing unit 320 can communicate directly with the HBS device 350 to retrieve subsets of data. For example, in the embodiments illustrated in FIG. 3, the processing unit 320 is directly coupled to the HBS device 350 through a third portion 346 of the SiP bus 340 that includes one or more route lines (one illustrated schematically in FIG. 3) formed into (or on) the base substrate 310. The direct coupling between the processing unit 320 and the HBS device 350 can allow a new subset of data to be loaded directly to the processing unit 320 at the start of a new operation (e.g., avoiding a buffer time associated with loading the subset into the HBM device 330 then loading the subset into the processing unit 320). Additionally, or alternatively, the direct coupling between the processing unit 320 and the HBS device 350 can allow the processing unit 320 to periodically save a state of the processing unit 320 directly to the HBS device 350 to create a non-volatile backup of the current state (e.g., after a predetermined amount of time, after a processing milestone, and/or the like).

However, as illustrated in FIG. 3, the third portion 346 of the SiP bus 340 can have a longer distance than either of the first and second portions 342, 344. The longer distance, in turn, can result in a lower bandwidth in the third portion 346 than in the first and second portions 342, 344, or higher manufacturing costs and/or operating power requirements to create and/or communicate data over longer route lines with the same bandwidth as the first and second portions 342, 344. In some embodiments, the reduction in bandwidth associated with the longer route lines in the third portion 346 results in large subsets of data being quicker to communicate through the first and second portions 342, 344 with the HBM device 330 as a buffer.

As further illustrated in FIG. 3, the SiP device 300 also includes interconnects 362 extending from the upper surface 312 of the base substrate 310 to a lower surface 314 of the base substrate 310. The interconnects 362 can provide an external connection for the processing unit 320, the HBM device 330, and the HBS device 350. For example, the interconnects 362 can couple any of the processing unit 320, the HBM device 330, and/or the HBS device 350 to an external component (e.g., a PCI bus coupled to an external storage, an external controller, and/or the like). Additionally, or alternatively, the interconnects 362 can couple any of the processing unit 320, the HBM device 330, and/or the HBS device 350 to a power source. Additionally, or alternatively, the interconnects 362 can couple any of the processing unit 320, the HBM device 330, and/or the HBS device 350 to a testing pin on the lower surface 314 of the base substrate 310 (e.g., to allow the processing unit 320, the HBM device 330, and/or the HBS device 350 to be evaluated after the SiP device 300 is assembled).

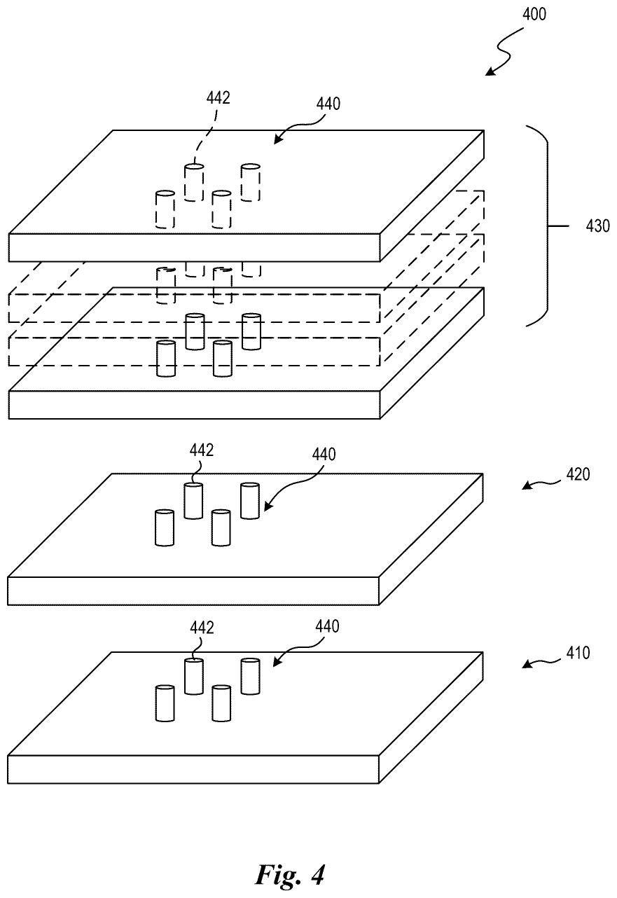

FIG. 4 is a partially schematic exploded view of an HBS device 400 configured in accordance with some embodiments of the present technology. For example, the HBS device 400 can be used as the HBS device 350 discussed above with reference to FIG. 3. In the illustrated embodiment, the HBS device 400 is a stack of dies that includes an interface die 410, one or more volatile memory dies 420 (one illustrated in FIG. 4), and one or non-volatile memory dies 430 (four illustrated in FIG. 4). Further, the HBS device 400 includes a shared HBM bus 440 communicatively coupling the interface die 410, the volatile memory die 420, and the non-volatile memory dies 430.

The interface die 410 can be a physical layer (“PHY”) that establishes electrical connections between the shared HBM bus 440 and external components of the shared HBM bus 440 (e.g., the route lines in the second portion 344 of the SiP bus 340 of FIG. 3). Additionally, or alternatively, the interface die 410 can include one or more active components, such as a static random access memory (SRAM) cache, a memory and/or storage controller, and/or any other suitable components. The volatile memory die 420 can be DRAM memory dies that provide low latency memory access to the HBS device 400 (e.g., acting as a buffer die for the HBS device 400). However, it will be understood that, in some embodiments, the HBS device 400 does not include any volatile memory dies. The non-volatile memory dies 430 (sometimes referred to herein as “storage dies,” “memory extension,” “memory extension dies,” and the like) can provide a non-volatile storage device (e.g., a NAND flash device) for the HBS device 400. Further, the non-volatile memory dies 430 can provide a significant extension of the available memory (e.g., two times, three times, four times, five times, ten times, one hundred times, or any other suitable increase) for a SiP device that the HBS device 400 is integrated into.

In a specific, non-limiting example, each of the non-volatile memory dies 430 can provide 64 GB of memory storage. As a result, the four non-volatile memory dies 430 illustrated in FIG. 4 provide a total memory capacity of 256 GB. In another specific, non-limiting example, each of the non-volatile memory dies 430 can provide 128 GB of memory. As a result, the four non-volatile memory dies 430 illustrated in FIG. 4 provide a total memory capacity of 512 GB. In yet another specific, non-limiting example, each of the non-volatile memory dies 430 can provide 256 GB of memory. As a result, the four non-volatile memory dies 430 illustrated in FIG. 4 provide a total memory capacity of 1024 GB. In each of these examples, a SiP device incorporating the HBS device 400 (e.g., the SiP device 300 of FIG. 3) can reduce (or avoid) the latency of loading memory from an external storage component (and through a low bandwidth communication channel) by loading data into the non-volatile memory dies 430 once, then accessing the data via the high bandwidth communication channels in the SiP bus discussed above.

As further illustrated in FIG. 4, the shared HBM bus 440 can include a plurality of TSVs 442 (four illustrated in FIG. 4, but any suitable number of TSVs is possible) extending from the interface die 410, through the volatile memory die 420, and through each of the non-volatile memory dies 430. Each of the TSVs 442 can support an independent, bidirectional read/write operation to communicate data between the dies in the HBS device 400 (e.g., between the interface die 410 and the volatile memory die 420, between the non-volatile memory dies 430 and the volatile memory dies 420, between the interface die 410 and the non-volatile memory dies 430, and the like). Because the TSVs 442 establish the shared HBM bus 440 between each of the dies in the HBS device 400, the shared HBM bus 440 can reduce (or minimize) the footprint needed to establish high bandwidth communication routes through the HBS device 400. As a result, the shared HBM bus 440 can reduce (or minimize) the overall footprint of the HBS device 400.

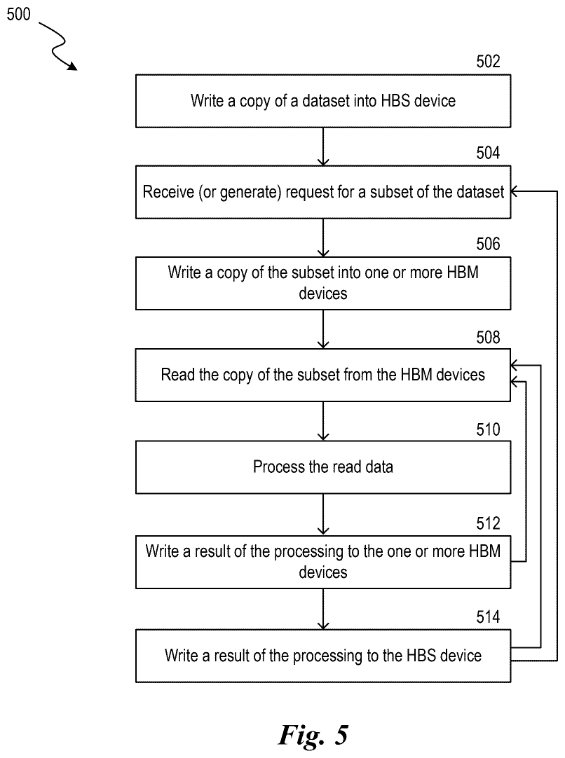

FIG. 5 is a flow diagram of a process 500 for operating a SiP device in accordance with some embodiments of the present technology. The process 500 can be completed by a controller in communication with the SiP device (e.g., a package controller) and/or on-board the SiP device (e.g., the processing unit 320 of FIG. 3, within the HBS device 350 of FIG. 3, and/or the like) to load, manage, and/or process data in the SiP device.

The process 500 begins at block 502 with writing data into an HBS device within the SiP device (e.g., the HBS device 350 of FIG. 3). In some embodiments, the data is written from an external storage component into the HBS device (e.g., via a PCI bus such as the third communication channel 256 of FIG. 2). In some such embodiments, the HBS device is large enough to store an entire data set for a complex computational operation (e.g., image and/or video rendering, AI/ML algorithms, and/or the like). In such embodiments, the data set must pass through a bottleneck to be loaded into the SiP device (e.g., through the PCI bus) only once. Afterward, the entire data set is available at a single location via a high bandwidth communication channel for any suitable number of iterations of the computational operation. In some embodiments, the SiP device includes multiple HBS devices and the data written into each HBS device is a partition of a larger data set. For example, a larger data set can be partitioned into two, three, four, and/or any other suitable number of parts for a corresponding number of HBS devices in a SiP and/or a corresponding number of SiP devices having one or more HBS devices. Additionally, or alternatively, the set of data can be partitioned according to an external requirement (e.g., according to a desired batch size for data in an AI/ML process, to maximize resource utilization during a computational process, and the like). In a specific, non-limiting example, a SiP device can include four HBS devices similar to the HBM devices discussed above with reference to FIGS. 3 and 4, each having a stack of non-volatile memory dies that provides 128 GB of memory. In this example, a data set with 512 GB of data can be portioned into four partitions of 128 GB, each of which can be loaded into a corresponding HBS device to be accessed during the AI/ML process. In some embodiments, the data is written from another suitable external component (e.g., a bus component coupled to another electronic device, a data capture device, an input/output device, and/or the like), for example when the HBS device stores a primary copy (and/or only) of data used by an electronic device that includes the SiP device.

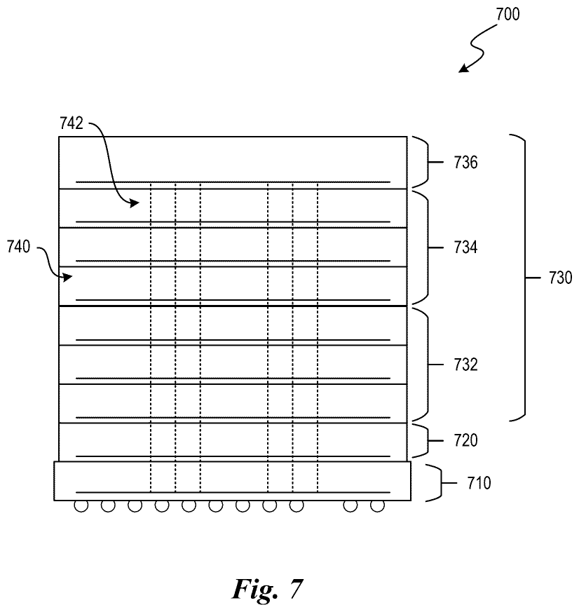

In some embodiments, the write operation at block 502 includes determining a role for one or more non-volatile memory dies in the HBS device. For example, a first subset of the non-volatile memory dies can be assigned as core dies, a second subset of the non-volatile memory dies can be assigned as spare dies, and a third subset of the non-volatile memory dies can be assigned as error correction code (ECC) dies. Additional details on the functionality of the subsets are discussed below with reference to FIG. 7.

Because the write operation at block 502 requires data to move from an external storage component and/or another external device into the HBS device, the write operation can require the data to move through a relatively low bandwidth bus (e.g., on the order of 8 GB/s in the bottleneck described above with reference to FIG. 1). Consequently, the write operation can take several seconds to complete. However, as discussed in more detail below, the data is then available via a high bandwidth communication path within the SiP device, allowing the data to be used any number of times without going through the bottleneck again.

At block 504, the process 500 includes receiving (or generating) a request for a subset of the data in the HBS device. The request can be received from, for example, a CPU/GPU in a SiP device and/or any other suitable controller. Additionally, or alternatively, the request can be generated by a controller in the HBS device (e.g., by the interface die 410 of FIG. 4) in anticipation of the data being needed by an external component and/or based on a previous request from the external component. In some embodiments, receiving the request causes the HBS device (e.g., via a controller in the interface die) to check whether the requested subset of the data is stored in a volatile memory die in the HBS device. When the requested subset is found in a volatile memory die, the process 500 can continue to block 506 (e.g., when the subset is written to the volatile memory die in anticipation of the request), else the process 500 must retrieve the data from one or more non-volatile memory dies in the HBS device.

At block 506, the process 500 includes writing a copy of the subset of the data (or causing the subset of the data to be written), from the HBS device, into one or more HBM devices in the SiP device (e.g., the HBM device 330 of FIG. 3) and/or directly to the processing device in the SiP device. The write operation can use a portion of a SiP bus between the HBS device and the HBM device (e.g., the second portion 344) and/or between the HBS device and the processing device (e.g., the third portion 346) to write the requested subset via a high bandwidth communication path. As a result, the write operation at block 506 can be executed in a timeframe on the order of tens of microseconds, such that the subset is available almost instantly. Once stored in the HBM device, the subset of the data is available for typical use by a controller and/or processing unit via a high bandwidth communication path (e.g., via the first portion 342 of the SiP bus 340 of FIG. 3).

At block 508 the process 500 includes reading the subset of the data in the HBM device. The read operation can move a copy of the subset (and/or a portion of the subset) into a processing unit (e.g., the processing unit 320 of FIG. 3) via another portion of the SiP bus (e.g., the first portion 342 of the SiP bus 340 of FIG. 3). At block 510, the process 500 includes processing the read subset of the data (e.g., at the processing unit 320 of FIG. 3). And at block 512, the process 500 can write a result of the processing at block 510 to the HBM device through the high bandwidth communication path. Because the read/write operations at blocks 508, 512 can communicate the data using the high bandwidth communication path, the subset of the data is available for processing within tens of microseconds, and/or the result of the processing is saved within tens of microseconds, such that the processing at block 510 is usually the limiting factor on the speed of the process 500 through blocks 508-512. After writing a result of the processing to the HBM device at block 512, the process 500 can return to block 508 to repeat blocks 508-512 any suitable number of times (e.g., when the processing at block 510 is part of an AI/ML algorithm that iteratively processes the subset of the data), and/or can return to block 504 to receive (or generate) a request for a second subset of the data in the HBS device and write the second subset of the data to the HBM device for processing.

Additionally, or alternatively, at block 514 the process 500 includes writing a result of the processing to the HBS device. In some embodiments, the write at block 514 writes the result of the processing from the processing unit directly to the HBS device (e.g., through the third portion 346 of the SiP bus 340 of FIG. 3). In some such embodiments, the write at block 514 can occur simultaneously (or generally simultaneously) with the write at block 512. Additionally, or alternatively, the write at block 514 can be executed instead of the write at block 512. In some embodiments, the write at block 514 writes the result of the processing from the HBM device to the HBS device (e.g., through the second portion 344 of the SiP bus 340 of FIG. 3). After writing a result of the processing to the HBS device at block 514, the process 500 can return to block 508 to repeat blocks 508-512 any suitable number of times (e.g., when the processing at block 510 is a part of an AI/ML algorithm that iteratively processes the subset of the data, when the write at block 514 saves an intermediate result of the processing during a long processing operation, and/or the like), and/or can return to block 504 to receive (or generate) a request for a second subset of the data in the HBS device and write the second subset of the data to the HBM device for processing.

In various specific, non-limiting examples, the process 500 can be part of an AI/ML algorithm, a video rendering process, a high-resolution graphics rending process, various complex computer simulations, and/or any other suitable computing applications. In such embodiments, the CPU/GPU will typically call and/or refer to each subset of the data more than once. As a result, the SiP architecture discussed above with reference to FIGS. 2-4 allows the process 500 to avoid reading the data from a storage component (and through a low bandwidth communication channel) multiple times. Instead, the data is written into the HBS device(s) once, then written to the HBM device(s), and read any suitable number of times. While the initial writing operation is subject to the bottleneck constraints of the low bandwidth communication path from the storage component, each subsequent access of the subset of the data (and/or accessing each subset sequentially) uses a high bandwidth path. As a result, each subsequent use of the data can require tens of microseconds instead of one or more seconds, potentially increasing the speed of the processing operations by orders of magnitude.

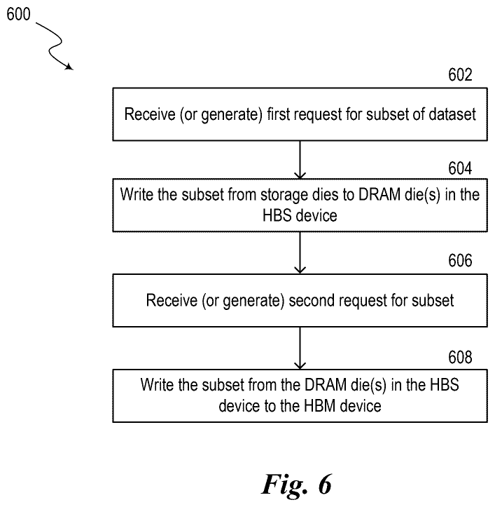

FIG. 6 is a flow diagram of a process 600 for operating a high bandwidth storage device in accordance with some embodiments of the present technology. The process 600 can be implemented by a storage controller within an interface die of an HBS device (e.g., the interface die 352 in the HBS device 350 of FIG. 3) and/or another suitable controller in a SiP device (e.g., by a controller at the processing unit 320 of FIG. 3).

The process 600 begins at block 602 with receiving (or generating) a first request for a subset of the data in the HBS device. The first request can be received from, for example, a CPU/GPU in a processing unit of a SiP device and/or any other suitable controller in anticipation of the data being needed by an external component (e.g., needed by the CPU/GPU) in the future. Purely by way of example, the first request can be received 10 cycles, 100 cycles, 1000 cycles, and/or any other suitable number of cycles before the anticipated need for the data. The first request allows the HBS device to check whether the requested subset of the data is available in a DRAM die in the HBS device (e.g., the volatile memory die 354 of FIG. 3). If not, at block 604, the process 600 includes writing the subset of the data from one or more storage dies (e.g., any of the non-volatile memory dies 356 of FIG. 3) to the DRAM die in the HBS device. As a result, the subset of the data is available in a faster component in response to the anticipated future need.

At block 606, the process 600 includes receiving (or generating) a second request for the subset of the data in the HBS device. The second request corresponds to the anticipated need for the subset of the data and can be received from, for example, a CPU/GPU in the processing unit of the SiP device. Responsive to receiving the second request, at block 608, the process 600 includes writing the subset of the data from the DRAM die in the HBM device to an HBM device in the SiP. The write at block 608 can be generally similar to the write at block 506 of FIG. 5 to make the subset of data available for processing at the processing unit.

FIG. 7 is a partially schematic cross-sectional diagram of an HBS device 700 configured in accordance with further embodiments of the present technology. As illustrated in FIG. 7, the HBS device 700 is generally similar to the HBS device 350 discussed above with reference to FIG. 3. For example, the HBS device 700 can include an interface die 710, as well as one or more volatile memory dies 720 (one illustrated in FIG. 7) and one or more non-volatile memory dies 730 (seven illustrated in FIG. 7) carried by the interface die 710. Further, each of the dies in the HBS device is communicatively coupled by TSVs 742 in an HBS bus 740.

In the illustrated embodiment, however, the non-volatile memory dies 730 are divided into three groups to support the operation of the HBS device 700 and/or the SiP device as a whole. More specifically, the non-volatile memory dies 730 can include one or more core dies 732 (three illustrated in FIG. 7), one or more spare dies 734 (three illustrated in FIG. 7), and/or one or more ECC dies 736. The core dies 732 can be used to implement any of the functions discussed above (e.g., to store sets of data, write subsets of data to HBM devices and/or processing units of the SiP device, and/or the like). The spare dies 734 can be redundant dies storing a secondary copy and/or back-up of data stored in the core dies 732 and/or can be used in place of any of the core dies 732 in the case of a failure (e.g., when one or more arrays in the core dies 732 fail, when an interconnection with one or more of the core dies 732 is broken, and/or the like). The ECC die 736 can function similarly to an ECC die for a DRAM memory device. For example, the ECC die 736 can store one or more ECC codes that are generated based on the actual data stored in the core dies 732. During a read of the core dies 732, a controller (e.g., a storage controller in the interface die 710) reads both the data from the core dies 732 and respective ECC codes from the ECC die 736, regenerates the ECC code from the data, and compares the regenerated code to the read code. If there is a match, then no errors have occurred with the actual data during storage and/or the read process. If there are mismatches, the ECC codes can allow the controller (or another suitable component) to correct various errors in the data before writing them outside of the HBS device.

As discussed above, the division of the non-volatile memory dies 730 can be controlled by a storage controller (e.g., a storage controller in the interface die 710) prior to the HBS device 700 receiving data and/or while the HBS device 700 receives data. Accordingly, in various other embodiments, other divisions of the non-volatile memory dies are possible. For example, because the ECC die 736 provides one layer of protection against errors in the data, the HBS device 700 can include six of the core dies 732, one of the ECC dies 736, and none of the spare dies 734. In another example, the HBS device 700 can include equal numbers of the core and spare dies 732, 734 and none of the ECC dies 736. In such embodiments, the HBS device 700 can lack the additional layer of protection against errors in the data, but can respond to read requests quicker (e.g., since no check of the ECC codes needs to be completed).

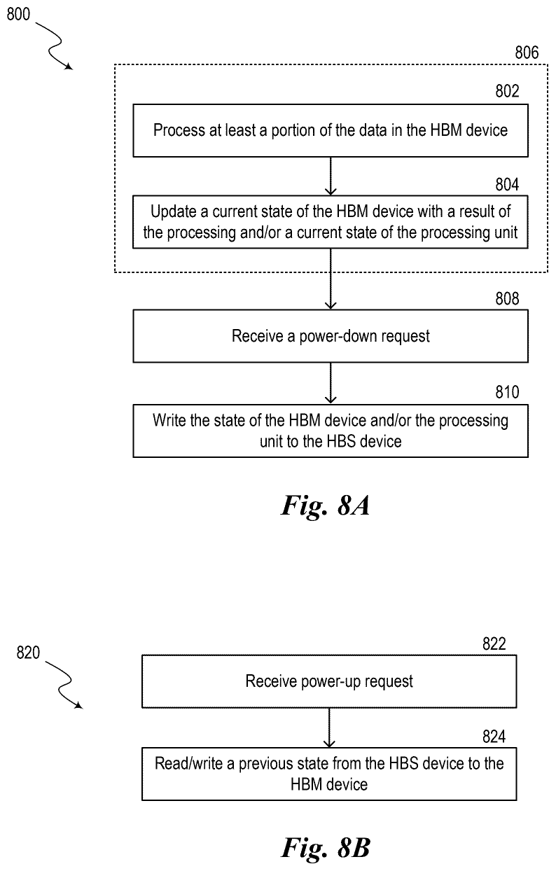

FIGS. 8A and 8B are flow diagrams of processes 800, 820 for powering a SiP device down and powering a SiP device up, respectively, using an HBS device in accordance with some embodiments of the present technology. The processes 800, 820 can be completed by a controller in communication with the SiP device (e.g., a package controller) and/or on-board the SiP device (e.g., the processing unit 320 of FIG. 3 and/or a controller on the interface die 410 of FIG. 4).

The process 800 of FIG. 8A begins at block 802 by processing at least a portion of the data in an HBM device in the SiP device. The processing at block 802 can be generally similar to (or the same as) the processing discussed above with reference to FIGS. 5 and 6. For example, the processing at block 802 can include reading a portion of the data in the HBM device into a processing unit and processing the read portion of the data.

At block 804, the process 800 includes updating a current state of the HBM device with a result of the processing at block 802 and/or a current state of the processing unit. The current state in the HBM device allows the result of the processing and/or a previous state of the processing unit to be recalled quickly as needed during processing (e.g., when an error occurs after the save, for further processing, and/or the like). In a specific, non-limiting example, the update at block 804 can save a state of the processing unit during a relatively long processing operation such that, in response to an error in the processing, the processing unit can return to a saved checkpoint rather than restarting completely.

The process 800 can complete blocks 802 and 804 (collectively, block 806) any number of times during operation of the SiP to support typical processing in a semiconductor device. During the processing and updates at block 806, the read/write operations can use a portion of a high bandwidth SiP bus between the processing unit and the HBM device (e.g., the first portion 342 of FIG. 3) to quickly communicate data back and forth between the HBM device and the processing components, allowing the read/write operations to not impose significant time constraints on the processing. Further, in some embodiments, the process 800 includes periodically writing to an HBS device in the SiP at block 806 to save a result of various processing operations, save a current state of the SiP device, a current state of the processing device, a current state of the HBM device, and/or any related information. Because the HBS device is also coupled to the SiP bus (e.g., to the second portion 344 and/or the third portion 346 of FIG. 3), the periodic saves can protect against a blackout, other loss of power, and/or various other sources of error without requiring a significant time investment and/or pause in processing operations. In a specific, non-limiting example, a processing operation can be expected to take multiple hours to complete. In this example, the process 800 can save a result of the processing operations and/or a current state of the SiP device every minute, every ten minutes, and/or at any other suitable interval to reduce the chance that the processing operation will have to completely start over (e.g., when power is lost, in response to a critical error, and/or the like).

At block 808, the process 800 includes receiving a power-down request (sometimes also referred to herein as an idle request). The power-down request can be received in response to an input from a user and/or another component of a system using the SiP device (e.g., to conserve power when an electronic device is running low on battery power and/or in response to a loss of power).

At block 810, the process 800 includes writing a state of the processing device, the HBM device, and/or any other suitable component of the SiP device to the HBS device. Because the HBS device is coupled to the SiP bus, the write operation can complete within tens of microseconds (e.g., as opposed to one or more seconds to write the data to a traditional storage device, such as the storage device 140 of FIG. 1). As a result, the SiP device can comply with the power-down request within tens of microseconds, allowing the semiconductor device to save power, reduce losses of data when power is lost, and/or otherwise shut off quickly when requested.

Relatedly, the process 820 of FIG. 8B can begin at block 822 by receiving a power-up request (sometimes also referred to herein as a wake-up request). The power-up request can be received in response to an input from a user and/or another component of a system using the SiP device (e.g., another controller in a semiconductor device). And at block 824 the process 820 can read/write a previous state of the SiP device from the HBS device to the HBM device, the processing device, and/or any other suitable components of the SiP device. Similar to the discussion above, because the HBS device is coupled to the SiP bus, the SiP device (and the corresponding semiconductor device) can respond to a power-up request within tens of microseconds (e.g., instead of the one or more seconds required to read/write from a traditional storage component). As a result, the SiP device (and the corresponding semiconductor device) can be ready for computational activities significantly faster than a conventional device.

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “generally”, “approximately,” and “about” are used herein to mean within at least within 10 percent of a given value or limit. Purely by way of example, an approximate ratio means within ten percent of the given ratio.

Several implementations of the disclosed technology are described above in reference to the figures. The computing devices on which the described technology may be implemented can include one or more central processing units, memory, input devices (e.g., keyboard and pointing devices), output devices (e.g., display devices), storage devices (e.g., disk drives), and network devices (e.g., network interfaces). The memory and storage devices are computer-readable storage media that can store instructions that implement at least portions of the described technology. In addition, the data structures and message structures can be stored or transmitted via a data transmission medium, such as a signal on a communications link. Thus, computer-readable media can comprise computer-readable storage media (e.g., “non-transitory” media) and computer-readable transmission media.

It will also be appreciated that various modifications may be made without deviating from the disclosure or the technology. For example, the dies in the HBM device can be arranged in any other suitable order (e.g., with the non-volatile memory die(s) positioned between the interface die and the volatile memory dies; with the volatile memory dies on the bottom of the die stack; and the like). Further, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments. For example, although discussed herein as using a non-volatile memory die (e.g., a NAND die and/or NOR die) to expand the memory of the HBM device, it will be understood that alternative memory extension dies can be used (e.g., larger-capacity DRAM dies and/or any other suitable memory component). While such embodiments may forgo certain benefits (e.g., non-volatile storage), such embodiments may nevertheless provide additional benefits (e.g., reducing the traffic through the bottleneck, allowing many complex computation operations to be executed relatively quickly, etc.).

Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

We claim:

1. A system-in-package (SiP) device, comprising:
a base substrate;
a processing unit carried by the base substrate;
a high bandwidth memory (HBM) device carried by the base substrate and electrically coupled to the processing unit through a SiP bus, wherein the HBM device comprises:
a first interface die;
one or more volatile memory dies carried by the first interface die; and
an HBM bus electrically coupled to the first interface die and each of the one or more volatile memory dies; and
a high bandwidth storage (HBS) device carried by the base substrate and electrically coupled to the HBM device through the SiP bus, wherein the HBS device comprises:
a second interface die;
one or more non-volatile memory dies carried by the second interface die; and
an HBS bus electrically coupled to the second interface die and each of the one or more non-volatile memory dies.

2. The SiP device of claim 1 wherein the second interface die includes a storage controller, the storage controller configured to:
receive a request for a subset of a data set stored in the one or more non-volatile memory dies;
read the subset of the data set from the non-volatile memory dies; and
send a copy of the subset of the data set dies to the one or more volatile memory dies in the HBM device.

3. The SiP device of claim 1 wherein the HBS device further comprises a volatile memory die carried by the second interface die and electrically coupled to the HBS bus.

4. The SiP device of claim 3 wherein the second interface die includes a storage controller, the storage controller configured to:
receive a first request for a subset of a data set stored in the one or more non-volatile memory dies;
write a copy of the subset of the data set from the one or more non-volatile memory dies to the volatile memory die carried in the HBS device;
receive a second request for the subset of the data set; and
send a copy of the subset of the data set from the volatile memory die carried in the HBS device to the one or more volatile memory dies in the HBM device.

5. The SiP device of claim 1 wherein the SiP bus comprises:
a first portion electrically coupled between the processing unit and the HBM device, wherein the first portion has a first bandwidth; and
a second portion electrically coupled between the HBM device and the HBS device, wherein the second portion has a second bandwidth generally equal to the first bandwidth.

6. The SiP device of claim 1 wherein the HBS device is directly electrically coupled to the processing unit through the SiP bus.

7. The SiP device of claim 1 wherein the one or more non-volatile memory dies in the HBS device are configured to provide a non-volatile copy of data stored in the one or more volatile memory dies in the HBM device accessible to the one or more volatile memory dies via the SiP bus in response to a power-up request.

8. A method, comprising:
generating a request for a subset of a set of data stored in a plurality of non-volatile memory dies in a high bandwidth storage (HBS);
writing a copy of the subset to a plurality of volatile memory dies in a high bandwidth memory (HBM) device;
reading the subset from the plurality of volatile memory dies into a processing unit;
processing, at the processing unit, the subset; and
writing a result of processing the subset to the plurality of volatile memory dies.

9. The method of claim 8 wherein the request for the subset of the set of data is a second request, wherein the copy of the subset of the set of data is a second copy, and wherein the method further comprises:
generating a first request for the subset of the set of data; and
writing a first copy of the subset to one or more volatile memory dies in the HBS device prior to generating the second request,
wherein writing the second copy of the subset to the plurality of volatile memory dies in the HBM device in response to the second request includes writing the second copy from one or more volatile memory dies in the HBS device to the plurality of volatile memory dies in the HBM device.

10. The method of claim 8, further comprising writing the result of processing the subset to the plurality of non-volatile memory dies.

11. The method of claim 8 wherein the processing unit is communicatively coupled to the plurality of volatile memory dies in the HBM device through a portion of a system-in-package (SiP) bus, and wherein reading the subset from the plurality of volatile memory dies into the processing unit includes communicating the subset through the portion of the SiP bus.

12. The method of claim 8 wherein the plurality of non-volatile memory dies in the HBS device are coupled to the plurality of volatile memory dies in the HBM device through a portion of a system-in-package (SiP) bus, and wherein writing the copy of the subset to the plurality of volatile memory dies in the HBM device includes communicating the subset through the portion of the SiP bus.

13. The method of claim 8, further comprising:
receiving a power down or idle request; and
in response to the power down or idle request, writing a current state of the plurality of volatile memory dies in the HBM device to the plurality of non-volatile memory dies in the HBS device through a system-in-package (SiP) bus.

14. The method of claim 8, further comprising, after a predetermined period while processing the subset, writing a current state of the processing unit and the plurality of volatile memory dies in the HBM device to the plurality of non-volatile memory dies in the HBS device through a system-in-package (SiP) bus.

15. The method of claim 8 wherein writing the set of data to the plurality of non-volatile memory dies in the HBS device includes:
assigning a first subset of the plurality of non-volatile memory dies in the HBS device to store a primary copy of the set of data; and
assigning a second subset of the plurality of non-volatile memory dies in the HBS device to store a secondary copy of the set of data.

16. The method of claim 8 wherein writing the set of data to the plurality of non-volatile memory dies in the HBS device includes:
assigning a first subset of the plurality of non-volatile memory dies in the HBS device to store a primary copy of the set of data; and
assigning a second subset of the plurality of non-volatile memory dies in the HBS device to function as an error correction code die.

17. A method, comprising:
updating a current state of a high bandwidth memory (HBM) device during a processing operation at a processing unit communicatively coupled to the HBM device;
receiving a power down or idle request; and
in response to the power down or idle request, controlling the HBM device to write the current state of the HBM device from the HBM device to a high bandwidth storage (HBS) device through a system-in-package (SiP) bus, wherein the HBS device includes one or more non-volatile memory dies.

18. The method of claim 17, further comprising, in response to the power down or idle request, writing a current state of the processing unit to the HBS device through the HBM device and the SiP bus.

19. The method of claim 17 further comprising:
receiving a power-up or wake up request; and
in response to the power-up or wake up request, controlling the HBS device to write, through the SiP bus, the current state of the HBM device from the HBS device back to the HBM device.

20. The method of claim 17 wherein writing the current state of the HBM device from the HBM device to the HBS device takes less than 100 milliseconds.
